(19) United States
(12) Patent Application Publication
(10) Pub. No.: US 2006/0284212 A1
(43) Pub. Date: Dec. 21, 2006

(54) Hetero-junction bipolar transistor and manufacturing method thereof

(75) Inventors: Keiichi Murayama, Toyama (JP); Akiyoshi Tamura, Osaka (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd, Osaka (JP)

(21) Appl. No.: 11/377,389

(22) Filed: Mar. 17, 2006

(30) Foreign Application Priority Data
Jun. 21, 2005 (JP) 2005-181113

(51) Int. Cl. H01L 31/00

(52) U.S. Cl. 257/197

(57) ABSTRACT

A high-performance hetero-junction bipolar transistor with good processibility and which does not increase ON resistance (Ron), and a manufacturing method thereof are provided. The hetero-junction bipolar transistor includes a sub-collector layer made of n-type GaAs, a second collector layer made of n-type GaAs having a lower impurity concentration than the impurity the sub-collector layer, and a first collector layer that is formed between the sub-collector layer and the second collector layer, and that has a resistance to an etchant used for etching the second collector layer and that allows conduction of electrons at a junction with the second collector layer.

### BACKGROUND OF THE INVENTION

(1) Field of the Invention

The present invention relates to a hetero-junction bipolar transistor.

(2) Description of the Related Art

In recent years, a Hetero-junction Bipolar Transistor (HBT) using, as an emitter, a semiconductor having a large band gap has come into practical use as a high-frequency analog device used in a cellular phone and the like (e.g. refer to Patent Reference 1, Japanese Laid-Open Patent Application No. 2001-168108). In particular, due to high reliability and processibility of an InGaP/GaAs HBT using InGaP for an emitter, the use of InGaP/GaAs HBT is expected to be extended to various fields (e.g. refer to Patent Reference 2, Japanese Laid-Open Patent Application No. 2003-297849).

A device structure of a general InGaP/GaAs HBT and a manufacturing method thereof are explained hereinafter with reference to drawings.

FIGS. 1A to 1D are cross-section diagrams showing a structure of an npn-type InGaP/GaAs HBT.

As shown in FIGS. 1A to 1D, an n⁺-type GaAs sub-collector layer 202 doped with a high concentration of an n-type impurity is laminated on a semi-insulating GaAs substrate 201.

Further, a GaAs collector layer 206 which is undoped or doped with a low impurity concentration of an n-type impurity, a high-concentrated p-type GaAs base layer 207, an n-type InGaP emitter layer 208 are sequentially laminated on the sub-collector layer 202. Also, these layers form a convex portion formed with a range restricted to the top of the sub-collector layer 202.

Further, an n-type GaAs emitter cap layer 209 and an n-type InGaAs emitter contact layer 210 with a low contact resistance are sequentially laminated on the emitter layer 208. Also, the emitter cap layer 209 and the emitter contact layer 210 form a second tier of the convex portion formed in a restricted range.

Furthermore, an emitter electrode 303 made of, for example, such as Ti/Pt/Au is formed on the emitter contact layer 210. A base electrode 302 is contacted with the base layer 207 by thermal diffusion on the emitter layer 208 exposed around the emitter cap layer 209. Also, a collector electrode 303 made of such as AuGe/Ni/Au is formed on the sub-collector layer 202. In order to electrically separate a unit HBT, a device separation region 304 ranging from the sub-collector layer 202 up to the substrate 201 is formed in a device neighboring region by ion implantation and inactivation heat-processing.

However, in the processing of etching to expose the sub-collector layer 202, an insufficient amount of etchant causes a failure in contacting with the sub-collector layer 202. On the other hand, an excessive amount of etchant decreases a volume of remaining portion of the sub-collector layer 202, causing an increase of collector resistance. Due to such factors, an etching stopper is inserted between the sub-collector layer 202 and the collector layer 206 so as to increase the etching precision. In general, as an etching stopper, InGaP with disordered lattice of 30 nm or smaller (hereafter referred to as disorder) is inserted. However, an insertion of the InGaP layer causes a band discontinuity (ΔEc) in conductors which becomes a barrier to the electron conduction. Consequently, there is a problem that the ON resistance (Ron) increases so that the characteristics of the HBT are degraded. SUMMARY OF THE INVENTION

An object of the present invention is to provide a high performance hetero-junction bipolar transistor with good processibility and which does not increase ON resistance (Ron), and a manufacturing method thereof.

In order to achieve the aforementioned object, a hetero-junction bipolar transistor according to the present invention includes: a sub-collector layer made of n-type GaAs; a collector layer made of n-type GaAs with a lower concentration than the n-type GaAs of the sub-collector layer; and a semiconductor layer that is formed between the sub-collector layer and the collector layer, and that is resistant to an etchant used for etching the collector layer and allows conduction of electrons at a junction with the collector layer.

Accordingly, the semiconductor layer serves an etching stopper in the etching processing of exposing the sub-collector layer so that etching reproducibility is improved. Further, a band discontinuity (ΔEc) in conductors that become a barrier to electrons are not caused since the electron conduction cannot be prevented. Consequently, etching can be performed so as to expose the sub-collector layer at a high precision. In addition, a high-performance HBT with good processibility which does not increase ON resistance (Ron) can be provided.

Further, the semiconductor layer may be made of InGaP in an ordered lattice.

Accordingly, since the semiconductor layer made of InGaP in an ordered lattice is rarely etched with phosphate/hydrogen peroxide type etchant (mixed solution of phosphate, hydrogen peroxide and water), the semiconductor layer serves as an etching stopper and the etching reproducibility is improved. Further, InGaP in an ordered lattice is a type II material at a junction with n-type GaAs that is a material for the collector layer so that the band discontinuity (ΔEc) in the conductors is not caused. Consequently, etching can be performed so as to expose the sub-collector layer at a high precision. In addition, a high-performance HBT with good processibility which does not increase ON resistance (Ron) can be provided.

It should be noted that the present invention may be realized not only as a hetero-junction bipolar transistor but also as a manufacturing method of the hetero-junction bipolar transistor.

As described above, compared to the conventional technology, the ON resistance can be set in low in the hetero-junction bipolar transistor according to the present invention. In addition, according to the manufacturing method of the hetero-junction bipolar transistor of the present invention, a high-performance HBT can be manufactured with a high processibility on a stable commission.

As further information about technical background to this application, the disclosure of Japanese Patent Application No. 2005-181113 filed on Jun. 21, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a cross section diagram showing a structure of a conventional HBT.

FIG. 1B is a cross section diagram showing a structure of the conventional HBT.

FIG. 1C is a cross section diagram showing a structure of the conventional HBT.

FIG. 1D is a cross section diagram showing a structure of the conventional HBT.

FIG. 2 is a cross section diagram showing a structure of HBT according to an embodiment of the present invention.

FIG. 3A is a band gap diagram for explaining a type I.

FIG. 3B is a band gap diagram for explaining a type II.

FIG. 4A is a cross section diagram showing a process of manufacturing a HBT according to the embodiment of the present invention.

FIG. 4B is a cross section diagram showing a process of manufacturing a HBT according to the embodiment of the present invention.

FIG. 4C is a cross section diagram showing a process of manufacturing a HBT according to the embodiment of the present invention.

FIG. 5A is a cross section diagram showing a process of manufacturing a HBT according to the embodiment of the present invention.

FIG. 5B is a cross section diagram showing a process of manufacturing a HBT according to the embodiment of the present invention.

FIG. 5C is a cross section diagram showing a process of manufacturing a HBT according to the embodiment of the present invention.

FIG. 6 is an Ic-Vc characteristic diagram according to the embodiment of the present invention.

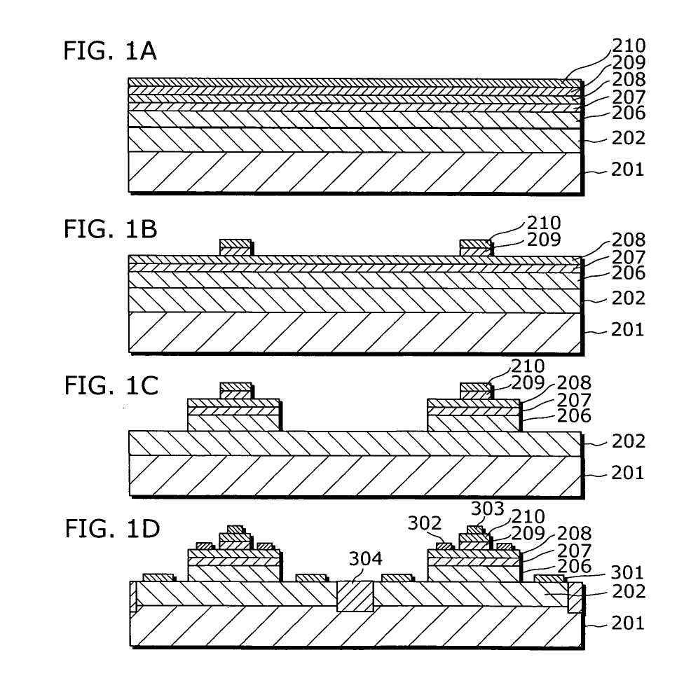

### DESCRIPTION OF THE PREFERRED EMBODIMENT(S)

### Embodiment

The embodiment according to the present invention is described hereinafter with reference to diagrams.

A hetero-junction bipolar transistor according to the present invention includes a collector layer made up of the following layers sequentially formed on an n-type GaAs sub-collector layer: a first collector layer made of InGaP in an ordered n-type lattice and a second collector layer made of n-type GaAs with a lower concentration than the sub-collector layer. On the second collector layer, a p-type GaAs base layer and an n-type emitter layer that is made of a semiconductor material having a larger band gap than the base layer are sequentially formed.

Considering the aforementioned structure, the hetero-junction bipolar transistor in the present embodiment is described.

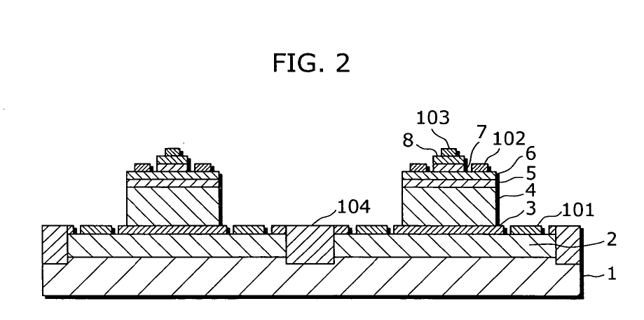

FIG. 2 is a cross-section diagram showing a structure of the hetero-junction bipolar transistor of the present invention. As shown in FIG. 2, the hetero-junction bipolar transistor (hereafter referred to as HBT) includes a sub-collector layer 2 formed on a semi-insulating GaAs substrate 1. In addition, a first collector layer 3, a second collector layer 4, a base layer 5 and an emitter layer 6 are sequentially laminated on the sub-collector layer 2, and this laminated structure forms a double-tier convex portion on the sub-collector layer 2.

Here, the sub-collector layer 2 is made of n⁺-type GaAs doped with an n-type impurity at a high impurity concentration of 5×10¹⁸ cm⁻³. The first collector layer 3 is made of ordered (in a state of ordered lattice) In_{0.48}GaP whose thickness is 20 nm doped with 1×10¹⁸ cm⁻³ impurity concentration of an n-type impurity. The second collector layer 4 is made of GaAs whose thickness is 500 nm doped with 1×10¹⁶ cm⁻³ low impurity concentration of an n-type impurity. The base layer 5 is made of GaAs whose thickness is 100 nm doped with 4×10¹⁹ cm⁻³ impurity concentration of a p-type impurity. The emitter layer 6 is made of In_{0.48}GaP whose thickness is 50 nm in which an In composition ratio is about 48 percent doped with 1×10¹⁸ cm⁻³ impurity concentration of an n-type impurity.

Also, in a portion where the first collector layer 3 and the second collector layer 4 are removed, AuGe/Ni/Au is formed by vapor deposition as a collector electrode 101 on the sub-collector layer 2. Further, Pt/Ti/Pt/Au is formed on the emitter layer 6 as an emitter electrode 103, and Pt/Ti/Pt/Au is formed as a base electrode 102 in a portion where the emitter layer 6 is exposed around the emitter cap layer 7. The base electrode 102 is diffused up to the base layer 5 by heat processing and is ohmic contacted.

The ordered In_{0.48}GaP that is a semiconductor material of the first collector layer 3 serves as an etching stopper because it is rarely etched in the etching processing of exposing the sub-collector layer 2, that is, with an etchant used in the etching processing of the second collector layer 4, for example, with a phosphate/hydrogen peroxide type etchant (mixed solution of phosphate, hydrogen peroxide and water). Further, it is a type II material against GaAs of the second collector layer 4 so that a band discontinuity (ΔEc) in the conductors being a barrier to electrons is not caused at a junction with the second collector layer 4.

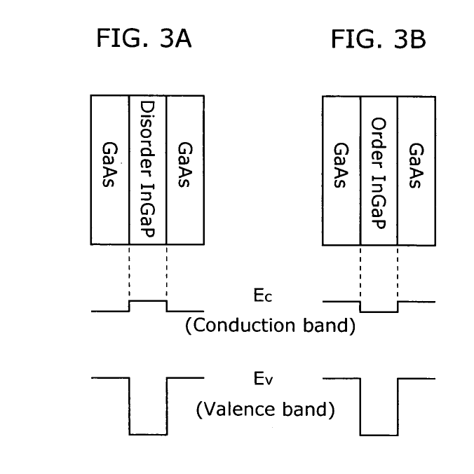

Here, in regard to type II, there are junction-types called type I and type II in the hetero-junction. Specifically, as shown in FIG. 3A, commonly-used disordered (in a state of disordered lattice) InGaP is a semiconductor material whose conduction band and valence band become barriers to GaAs. This is called type I. On the other hand, as shown in FIG. 3B, ordered (in a state of ordered lattice) InGaP is a semiconductor material whose valence band becomes a barrier while the conduction band does not become a barrier. This is called type II.

Accordingly, the InGaP layer that is the first collector layer 3 serves as an etching stopper in the etching processing of exposing the sub-collector layer 2, that is, in the etching processing of the second collector layer. Therefore, etching reproducibility is improved. Note that, the inserted InGaP is an ordered type II material against GaAs that is a material of the second collector layer 4 so that ΔEc is not caused.

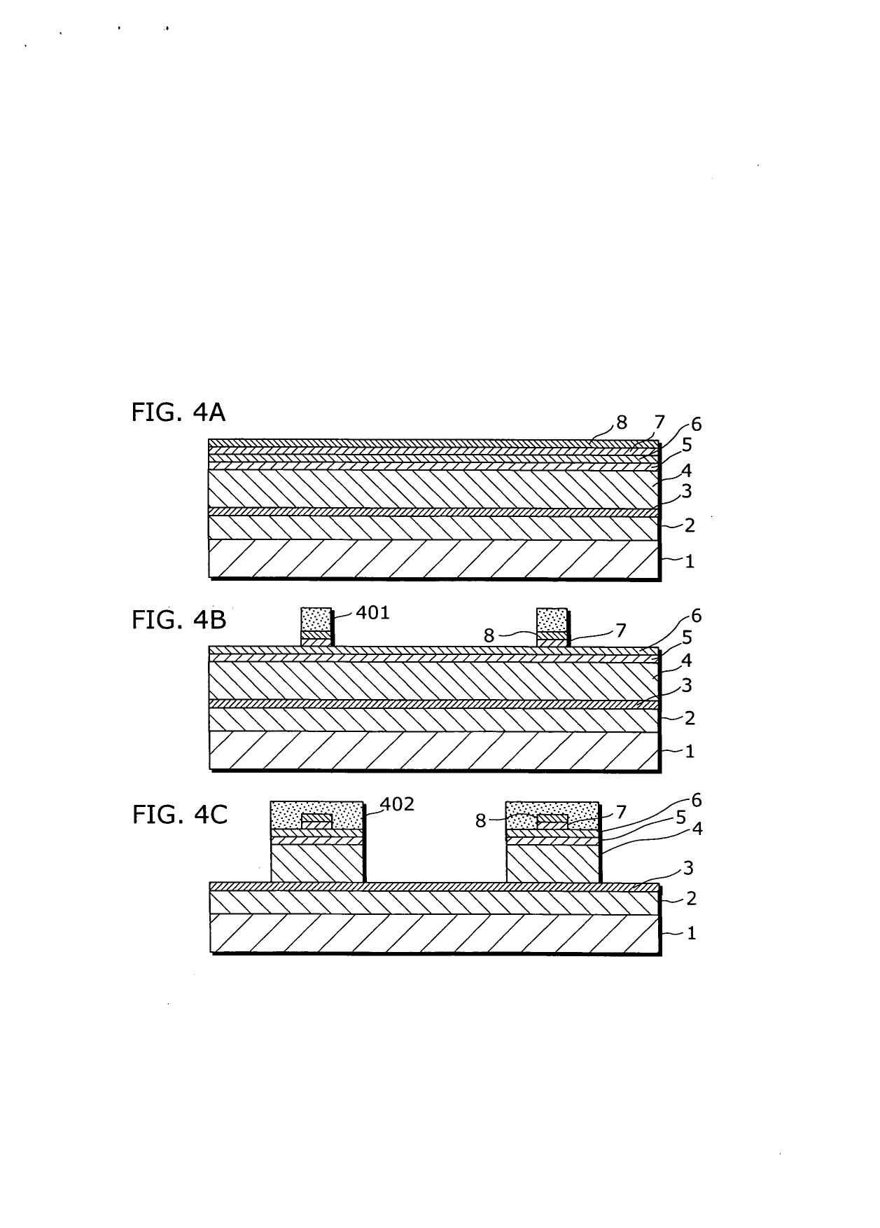

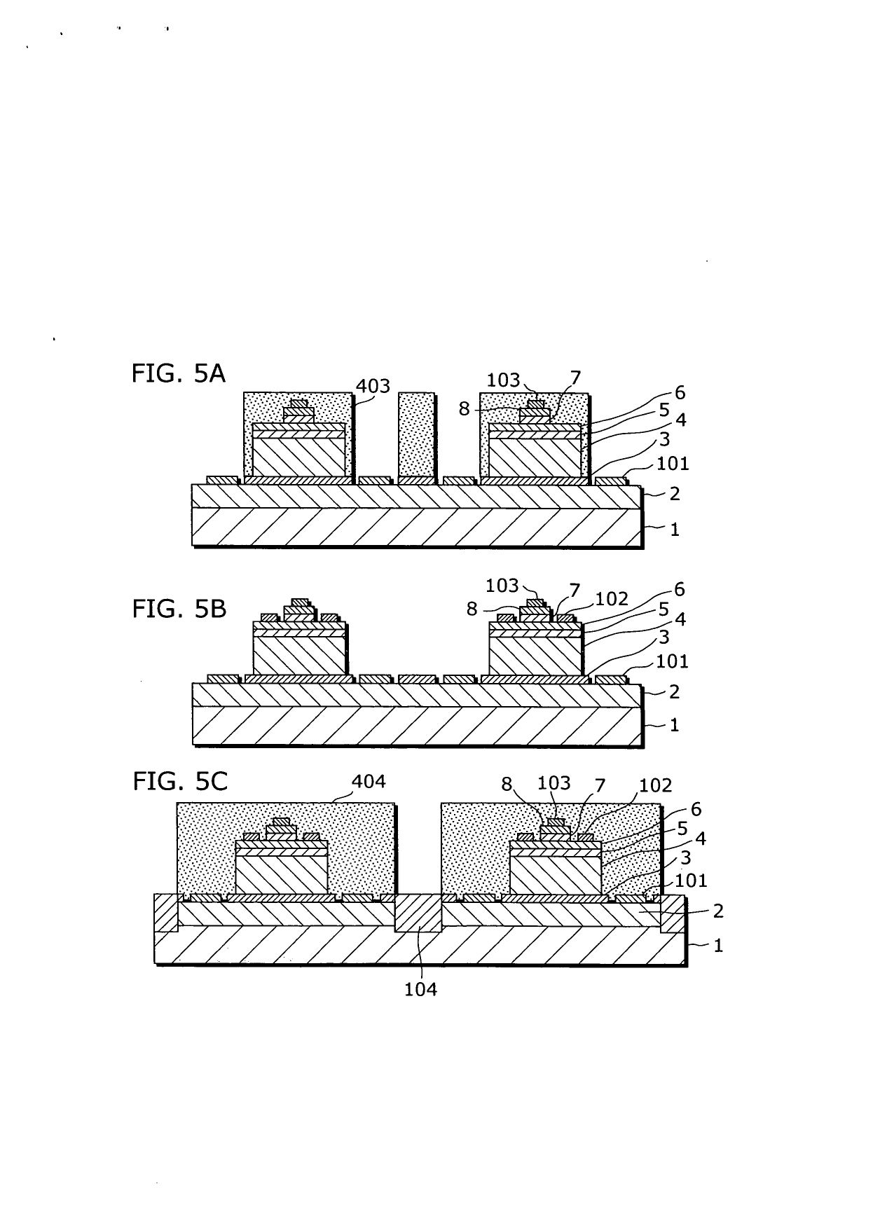

Next, a method of manufacturing a HBT is described with references to FIG. 4 and FIG. 5.

First, as shown in FIG. 4A, using a crystal growth method such as a Molecular Beam Epitaxy (MBE) method and a Metal Organic Chemical Vapor Deposition (MOCVD) method, the following layers are laminated on 1) a semi-insulating GaAs substrate 1: 2) a sub-collector layer 2, for example, made of n⁺-type GaAs doped with 5×10¹⁸ cm⁻³ high impurity concentration of an n-type impurity; 3) a first collector layer 3 whose thickness is 20 nm, for example, made of ordered In_{0.48}GaP doped with 1×10¹⁸ cm⁻³ impurity concentration of an n-type impurity; 4) a second collector layer 4 whose thickness is 500 nm made of GaAs doped with 1×10¹⁶ cm⁻³ low impurity concentration of an n-type impurity; 5) a base layer 5 whose thickness is 100 nm, for example, made of GaAs doped with 4×10¹⁹ cm⁻³ impurity concentration of a p-type impurity; 6) an emitter layer 6 whose thickness is 50 nm, for example, made of In_{0.48}GaP doped with 1×10¹⁸ cm⁻³ impurity concentration of an n-type impurity; 7) an emitter cap layer 7 whose thickness is 200 nm, for example, made of GaAs doped with 3×10¹⁸ cm⁻³ impurity concentration of an n-type impurity; and 8) an emitter contact layer 8 whose thickness is 100 nm made of InGaAs doped with 1×10¹⁹ cm⁻³ impurity concentration of an n-type impurity.

Following that, as shown in FIG. 4B, covering an emitter formation region with a photoresist 401, an emitter island-shaped region is formed by sequentially etching the emitter contact layer 8 (n-type InGaAs) and the emitter cap layer 7 (n-type GaAs) with phosphate/hydrogen peroxide type etchant (mixed solution of phosphate, hydrogen peroxide and water). Herein, the emitter layer 6 (n-type In_{0.48}GaP) is rarely etched with the phosphate/hydrogen peroxide type etchant (mixed solution of phosphate, hydrogen peroxide and water).

After that, as shown in FIG. 4C, covering a base formation region with another photoresist 402, a base island-shaped region is formed by selectively etching the emitter layer 6 (n-type In_{0.48}GaP) with diluted hydrochloric acid, and by sequentially removing the base layer 5 (p-type GaAs) and the second collector layer 4 (n-type GaAs) using the emitter layer 6 as a mask with phosphate/hydrogen peroxide type etchant (mixed solution of phosphate, hydrogen peroxide and water). Herein, the first collector layer 3 (ordered In_{0.48}GaP) serves as an etching stopper against the phosphate/hydrogen peroxide type etchant (mixed solution of phosphate, hydrogen peroxide and water). Therefore, etching for forming a base island-shaped region can be performed at high processing precision and with good reproducibility.

Next, as shown in FIG. 5A, a photoresist 403 is formed so as to leave open a region where the collector electrode is formed, and the first collector layer 3 (ordered In_{0.48}GaP) is selectively etched with diluted hydrochloric acid. The sub-collector layer 2 (n⁺-type GaAs) is rarely etched with the diluted hydrochloric acid so that the sub-collector layer 2 (n⁺-type GaAs) is stably remained.

Following that, AuGe/Ni/Au is formed by vapor deposition as a collector electrode 101 and form the collector electrode by lifting-off metals on the photoresist.

Next, as shown in FIG. 5B, an emitter/base electrodes are formed by resist patterning for forming the emitter electrode and the base electrode, evaporating Pt/Ti/Pt/Au all over the wafer, and using an evaporation lift-off method.

After that, as shown in FIG. 5C, a photoresist 404 is formed so as to cover each HBT region; He ion is implanted to the first collector layer 3 (ordered In_{0.48}GaP) and the sub-collector layer 2 (n⁺-type GaAs); and appropriate heat processing of inactivating carriers in the sub-collector layer between devices is performed. Consequently, HBTs are electrically separated from each other. Through aforementioned processing, a device separation region 104 is formed. With this heat processing, the emitter electrode 101, base electrode 102, and collector electrode 103 are respectively alloyed and a HBT shown in FIG. 2 is completed.

In specific, at least through the following processes of 1) to 7), a hetero-junction bipolar transistor according to the present embodiment is manufactured.

1) Sequentially forming the following layers on one side of the semi-insulating GaAs substrate 1: the sub-collector layer 2 made of a high impurity concentration of n⁺-type GaAs; a first collector layer 3 made of n-type InGaP in an ordered lattice; a second collector layer 4 made of a low impurity concentration of n-type GaAs; a base layer 5 made of a high impurity concentration of p-type GaAs; an emitter layer 6 made of n-type In_{0.48}GaP; an emitter cap layer 7 made of n-type GaAs; and an emitter contact layer 8 made of n-type InGaAs.

2) Forming an emitter island-shaped region by etching predetermined regions of the emitter contact layer 8 and the emitter cap layer 7 with a phosphate/hydrogen peroxide type etchant (mixed solution of phosphate, hydrogen peroxide and water).

3) Etching, with diluted hydrochloric acid, the emitter layer 6 so as to form a region exceeding an outer edge of the emitter island-shaped region.

4) Etching, with a phosphate/hydrogen peroxide type etchant (mixed solution of phosphate, hydrogen peroxide and water), the base layer 5 and the second collector layer 4 using the emitter layer 6 as a mask.

5) Etching, with diluted hydrochloric acid, the first collector layer 3 exposed outside the base island-shaped region so as to expose the sub-collector layer 2 and to open a region where the collector electrode 101 is to be formed.

6) Forming a collector electrode 101 on the exposed sub-collector layer 2.

7) Forming respectively an emitter electrode 103 on the emitter layer 6 and a base electrode 102 on the emitter island-shaped region of the emitter contact layer 8.

Here, a static characteristic of the HBT manufactured according to the embodiment of the present invention is described.

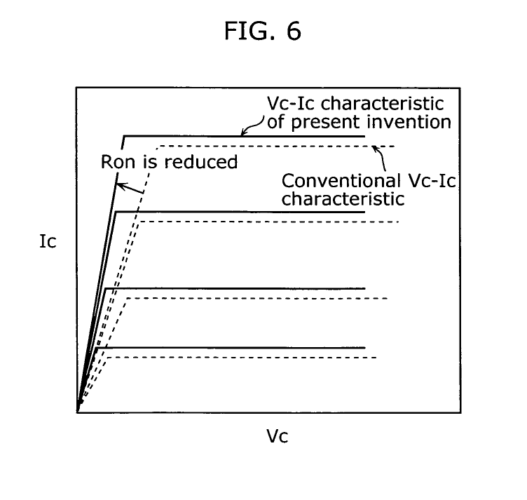

As shown in FIG. 6, a dashed line in the diagram indicates a characteristic in the case where conventional disordered InGaP is used for the first collector layer 3, while a solid line indicates a characteristic in the case where ordered InGaP is used. Comparing between the dashed lines and solid lines, when ordered InGaP is used for the first collector layer, ON resistance (Ron) is reduced and a high performance HBT is manufactured.

As described above, in the hetero-junction bipolar transistor according to the present embodiment, the InGaP layer that is the first collector layer 3 serves as an etching stopper in the etching processing of exposing the sub-collector layer 2 so that etching reproducibility is improved. Note that, the inserted InGaP is an ordered type II material against GaAs that is a material of the second collector layer 4, so that ΔEc is not caused. Accordingly, etching for exposing the sub-collector layer at a good precision can be performed. As the result, a high performance HBT with good processibility which does not increase ON resistance (Ron) can be provided.

Note that, while ordered InGaP that is the first collector layer 3 is removed only from the region where the contact electrode is to be formed, it may be removed after the removal of the second collector layer 4 in the process of forming a base island-shaped region. In this case, since the first collector layer 3 except the HBT region is totally removed, the semiconductor material exposed to the top surface of a wafer becomes GaAs, leading an advantage of good adherence of an insulating film.

Note that, while InGaP is used for the first collector layer 3 and as an etching stopper layer against a phosphate/hydrogen peroxide type etchant (mixed solution of phosphate, hydrogen peroxide and water), AlGaAs may be used for the first collector layer 3. In this case, when a citrate/hydrogen peroxide type etchant is used, AlGaAs servers as an etching stopper layer. Therefore, the etching processing precision at the time of forming a base island-shaped region can be greatly increased as in the case of using InGaP.

Note that, in the present embodiment, ordered n-type InGaP that is a type II semiconductor material against GaAs is used for the first collector layer 3. However, not only limited to the above, similar effect can be obtained using a material, for example, such as InGaAs and GaAsSb which do not cause ΔEc.

Also, while n-type InGaP is used for the emitter layer 6, in general, a material such as AlGaAs having a larger band gap than GaAs that is a material of the base layer may be used.

Note that, while a thickness of the second collector layer 4 is defined as 500 nm, in the case of a high frequency analog device used for a high-output Global System for Mobile Communications (GSM) method, the thickness of the collector layer is necessary to be set 1.0 μm or more. For improving the etching reproducibility, further effect of the present invention is expected.

Note that, while specific numbers are used in the embodiment of the present invention, those numbers are only limited as examples and do not restrict the scope of the present invention.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention can be used as a hetero-junction bipolar transistor and the like, in particular, as a hetero-junction bipolar transistor used as a high frequency analog device.

What is claimed is:

1. A hetero-junction bipolar transistor comprising
a sub-collector layer made of n-type GaAs;
a collector layer made of n-type GaAs with a lower concentration than the n-type GaAs of said sub-collector layer; and
a semiconductor layer that is formed between said sub-collector layer and said collector layer, and that is resistant to an etchant used for etching said collector layer and allows conduction of electrons at a junction with said collector layer.

2. The hetero-junction bipolar transistor according to claim 1,
wherein said semiconductor layer, is made of InGaP in an ordered lattice.

3. The hetero-junction bipolar transistor according to claim 2, further comprising:
a base layer made of p-type GaAs; and
an n-type emitter layer made of a semiconductor material having a greater band gap than said base layer,
wherein said base layer and said n-type emitter layer are sequentially formed on said collector layer.

4. The hetero-junction bipolar transistor according to claim 1, further comprising:
a base layer made of p-type GaAs; and
an n-type emitter layer made of a semiconductor material having a greater band gap than said base layer,
wherein said base layer and said n-type emitter layer are sequentially formed on said collector layer.

5. A method of manufacturing a hetero-junction bipolar transistor, comprising:
forming the following layers sequentially on one side of a semiconductor substrate: a sub-collector layer made of n-type GaAs with a high impurity concentration; a first collector layer made of n-type InGaP in an ordered lattice; a second collector layer made of n-type GaAs with a low impurity concentration; a base layer made of p-type GaAs with a high impurity concentration; an emitter layer made of n-type InGaP; an emitter cap layer made of n-type GaAs; and an emitter contact layer made of n-type InGaAs;
forming an emitter island-shaped region by etching, with a first etchant, predetermined regions of the emitter contact layer and the emitter cap layer;
etching the emitter layer with a second etchant so as to form a region exceeding an outer edge of the emitter island-shaped region;
etching the base layer and the second collector layer using the emitter layer as a mask, with a third etchant which is less reactive to the first collector layer;
opening a collector electrode formation region by etching, with a fourth etchant, the first collector layer exposed outside the base island-shaped region so as to expose the sub-collector layer;
forming a collector electrode on the exposed sub-collector layer; and
forming respectively an emitter electrode on the emitter layer and a base electrode on the emitter contact layer of the emitter island-shaped region.
